(19) United States
(12) Patent Application Publication
(10) Pub. No.: US 2026/0182104 A1
(43) Pub. Date: Jun. 25, 2026

(54) Curved Light Emitting Display Device and Cockpit System

(71) Applicant: LG Display Co., Ltd., Seoul (KR)

(72) Inventors: SeHong Park, Paju-si (KR); Hyeonhye Yu, Paju-si (KR); YoungNam Lim, Paju-si (KR); DaeHeung Lee, Paju-si (KR)

(21) Appl. No.: 19/339,216

(22) Filed: Sep. 24, 2025

(30) Foreign Application Priority Data
Dec. 24, 2024 (KR) 10-2024-0196267

(51) Int. Cl. H10H 20/856; H10H 20/84; H10H 29/37; H10K 50/84; H10K 50/856; H10K 59/122; H10K 77/10

(52) U.S. Cl. CPC H10H 20/856; H10H 20/84; H10H 29/37; H10K 50/84; H10K 50/856; H10K 59/122; H10K 77/111

(57) ABSTRACT

A curved light emitting display device is presented herein. The curved light emitting display device includes a substrate, a flat section on the substrate, a rightward curved section disposed at one side of the flat section on the substrate, and a leftward curved section disposed at another side of the flat section on the substrate. Luminance deviation among a left viewing angle luminance of the rightward curved section, a frontal luminance of the flat section and a right viewing angle luminance of the leftward curved section is out of the perceptible range.

### CROSS-REFERENCE TO RELATED APPLICATION

This application claims priority to Republic of Korea Patent Application No. 10-2024-0196267 filed on Dec. 24, 2024, which is incorporated by reference in its entirety.

### BACKGROUND

### Field

The present disclosure relates to a curved light emitting display device and cockpit system having the same.

### Description of the Related Art

Recently, a display device is being developed that integrates a dashboard in front of the driver's seat, the AVN system (audio, video, navigation system) and the center information display (CID). A driver seat system (or ‘cockpit system) that applies the integrated display to automobiles, airplanes and ships has been developed. The cockpit system may comprise a dashboard and a windshield (or windscreen) located above the dashboard.

Dashboard refers to the ‘instrument panel’ in front of the driver's seat of a car or airplane that displays various information necessary for driving, such as the speedometer, engine RPM, remaining fuel level and so on. A vehicle cockpit system uses a flexible panel display device applied to the dashboard to check situation including speed, direction, audio, video and traffic information and to control the vehicle.

The dashboard configuring the vehicle cockpit system may provide various information depending on various locations of the display. For example, information necessary for driving the vehicle may be provided in front section of the dashboard. The central section of the dashboard may contain controls and status information for auxiliary vehicle functions, such as the vehicle's air condition system and radio system. Additionally, an entertainment display section providing video information may be located in front of the passenger seat. To implement the entire dashboard as a single display device, a curved display device with repeated inflection sections and flat sections may be applied. The structural development may be needed to ensure that the information provided from a display device with long lateral length and various inflection sections may be accurately recognized by the driver located in front of the dashboard.

In particular, the inflection sections may appear dark to the driver and passengers positioned in front of the dashboard. Therefore, it may be necessary to develop a display device having a structure that can provide information with uniform luminance (or uniform luminance distribution) to the driver and/or passengers.

Further, the image information displayed on the dashboard may be reflected on the windshield and perceived by the driver and/or passengers. When the images from the dashboard may have a difference in luminance (or brightness), then the images reflected by the windshield may also have a difference in luminance, and then may affect the driver's vision. For example, when the image reflected on the windshield has dark and bright areas that are irregularly distributed, this reflected image may distract to the driver and then may cause danger.

### SUMMARY

The purpose of the present disclosure, as for solving the problems described above, is to provide a curved light emitting display device mounted on a cockpit system. In addition, another purpose of the present disclosure is to provide a cockpit system comprising a windshield positioned above the curved light emitting display device.

One or more embodiments of the present disclosure may provide a curved light emitting display device having a curved section and a long lateral length, which is mounted on a dashboard and provides image information with uniform luminance from the direction of the observer. In addition, the present disclosure may provide a cockpit system that is configured with a windshield placed above the curved light emitting display device, and provides a reflected image by the windshield with uniform luminance distribution.

In order to accomplish the above-mentioned purposes of the present disclosure, a curved light emitting display device according to the present disclosure comprises: a substrate; a flat section in the substrate; a right curved section disposed at one side of the flat section in the substrate; and a left curved section disposed at another side of the flat section in the substrate. Luminance deviation among a left viewing angle luminance of the right curved section, a frontal luminance of the flat section and a right viewing angle luminance of the left curved section is out of the perceptible range.

In an example, a luminance deviation between an upward viewing angle luminance of the flat section and projected luminance of any one of the right curved section and the left curved section is out of the perceptible range.

In an example, each of pixels in the right curved section includes: a first light emitting diode; and a first side mirror placed at left side of the first light emitting diode. Each of pixels in the flat section includes: a second light emitting diode; and a second side mirror placed at upper side of the second light emitting diode. Each of pixels in the left curved section includes: a third light emitting diode; and a third side mirror placed at right side of the third light emitting diode.

In an example, each of the first light emitting diode, the second light emitting diode and the third light emitting diode includes: an anode electrode; an emission layer on the anode electrode; and a cathode electrode on the emission layer. The first side mirror has a first inclined side which is a left side portion of the anode electrode extended to a left upward direction. The second side mirror has a second inclined side which is an upper side portion of the anode electrode extended to an upper upward direction. The third side mirror has a third inclined side which is a right side portion of the anode electrode extended to a right upward direction.

In an example, the first inclined side, the second inclined side and the third inclined side have an inclination angle of any one of between 20 degree and 40 degree and between 50 degree and 80 degree.

In an example, the curved light emitting display device further comprises: a first pixel in the right curved section; a second pixel in the flat section; and a third pixel in the left curved section. Each of the first pixel, the second pixel and the third pixel includes: an anode electrode; an emission layer on the anode electrode; a cathode electrode on the emission layer; and a passivation layer on the cathode electrode. The second pixel except the first pixel and the third pixel further include protrusions dispersed on the passivation layer.

In an example, the second pixel further includes a side mirror having inclined sides which are configured by that a left side portion and a right side portion of the anode electrode are extended to upward directions.

In an example, the inclined sides have an inclination angle between 40 degree and 50 degree.

In an example, the first pixel includes a first side mirror having a first inclined side which is a left side portion of the anode electrode extended to a left upward direction. The third pixel includes a second side mirror having a second inclined side which is a right side portion of the anode electrode extended to a right upward direction.

In an example, the first inclined side and the second inclined side have an inclination angle of any one of between 20 degree and 40 degree and between 50 degree and 80 degree.

In an example, the second pixel further includes a third side mirror having a third inclined side which is a right side portion and a left side portion of the anode electrode extended to an upward direction.

In an example, the first inclined side and the second inclined side have an inclination angle of any one of between 20 degree and 40 degree and between 50 degree and 80 degree. The third inclined side has an inclination angle between 40 degree and 50 degree.

In addition, a cockpit system according to the present disclosure comprises: a curved light emitting display device including a right curved section, a flat section and a left curved section; and a windshield disposed at front upper side of the curved light emitting display. A luminance deviation among a left viewing angle luminance of the right curved section, a frontal luminance of the flat section, an upward viewing angle luminance of the flat section and a right viewing angle luminance of the left curved section is out of a perceptible range. A reflection luminance deviation among a reflection luminance of the right curved section, a reflection luminance of the flat section and a reflection luminance of the left curved section is out of the perceptible range.

In an example, each of pixels in the right curved section includes: a first anode electrode; and a first side mirror having a first inclined side which is a left side portion of the anode electrode extended to a left upward direction. Each of pixels in the flat section includes: a second anode electrode; and a second side mirror having a second inclined side which is an upper side portion of the anode electrode extended to an upper upward direction. Each of pixels in the left curved section includes: a third anode electrode; and a third side mirror having a third inclined side which is a right side portion of the anode electrode extended to a right upward direction. The first inclined side, the second inclined side and the third inclined side have an inclination angle of any one of between 20 degree and 40 degree and between 50 degree and 80 degree.

In an example, the cockpit system further comprises: a first pixel in the right curved section; a second pixel in the flat section; and a third pixel in the left curved section. Each of the first pixel, the second pixel and the third pixel includes: an anode electrode; an emission layer on the anode electrode; a cathode electrode on the emission layer; and a passivation layer on the cathode electrode. The second pixel except the first pixel and the third pixel further includes protrusions dispersed on the passivation layer.

In an example, the second pixel further includes a side mirror having inclined sides which are configured by that a left side portion and a right side portion of the anode electrode are extended to upward directions. The inclined sides have an inclination angle between 40 degree and 50 degree.

In an example, the first pixel includes a first side mirror having a first inclined side which is a left side portion of the anode electrode extended to a left upward direction. The third pixel includes a second side mirror having a second inclined side which is a right side portion of the anode electrode extended to a right upward direction. The first inclined side and the second inclined side have an inclination angle of any one of between 20 degree and 40 degree and between 50 degree and 80 degree.

In an example, the second pixel further includes a third side mirror having a third inclined side which is a right side portion and a left side portion of the anode electrode extended to an upward direction. The third inclined side has an inclination angle between 40 degree and 50 degree.

In one or more embodiments, the curved light emitting display device includes a flat section, a rightward curved section disposed at a first side of the flat section, and a leftward curved section disposed at a second side of the flat section that is opposite to the first side. A a pixel in the leftward curved section includes a first anode electrode including a pair of flat portions and a sloped portion between the pair of flat portions, the sloped portion of the first anode electrode extending to a right upward direction, a first emission layer partially on the first anode electrode, the first emission layer including a pair of flat portions and a sloped portion between the pair of flat portions, and a first cathode electrode on the first emission layer, the first cathode electrode including a pair of flat portions and a sloped portion between the pair of flat portions. An inclination angle of each of the sloped portion of the first emission layer and the sloped portion of the first cathode electrode is greater than an inclination angle of the sloped portion of the first anode electrode.

A pixel in the rightward curved section includes a second anode electrode including a pair of flat portions and a sloped portion between the pair of flat portions, the sloped portion of the second anode electrode extending to a left upward direction, a second emission layer partially on the second anode electrode, the second emission layer including a pair of flat portions and a sloped portion between the pair of flat portions, and a second cathode electrode on the second emission layer, the second cathode electrode including a pair of flat portions and a sloped portion between the pair of flat portions. An inclination angle of each of the sloped portion of the second emission layer and the sloped portion of the second cathode electrode is greater than an inclination angle of the sloped portion of the second anode electrode.

The curved light emitting display device according to the present disclosure may have a feature in which the lateral length may be very long in the horizontal (or lateral) direction. In particular, a display device that provides information necessary for operation and control such as a dashboard installed in front of the cockpit of a vehicle, airplane or ship, may be implemented as a single light emitting display device.

The curved light emitting display device according to the present disclosure may be a display device having a long lateral length and various inflection sections, and may provide image information having the uniform luminance (or brightness) to a driver positioned in the front direction of the dashboard. Further, when an image provided by a curved light emitting display device is reflected by a windshield positioned upward, the device has a feature for evenly implementing the luminance of the reflected image. Therefore, the reflected light luminance of the image information may provide uniform luminance without severe deviation.

In addition to the effects of the present disclosure mentioned above, other features and advantages of the present disclosure are described below, or may be clearly understood by those skilled in the art from such descriptions and explanations.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view illustrating a schematic structure of a light emitting display device according to one or more embodiments of the present disclosure.

FIG. 2 is a circuit diagram illustrating a structure of one pixel disposed in a light emitting display device according to one or more embodiments of the present disclosure.

FIG. 3 is an enlarged plan view illustrating a structure of three pixels sequentially disposed in the light emitting display device according to one or more embodiments of the present disclosure.

FIG. 4 is a cross-sectional view, cutting along line I-I′ in FIG. 3, for illustrating a structure of one pixel in a light emitting display device according to one or more embodiment of the present disclosure.

FIG. 5 is a diagram illustrating the luminance deviation of each zone of a curved light emitting display device and the reflection luminance deviation reflected on windshield placed above in a cockpit according to one or more embodiments of the present disclosure.

FIG. 6 is schematic diagram explaining the relationship between the luminance of an image provided by a curved light emitting display device mounted on a dashboard and the reflection luminance of an image reflected on a windshield in a cockpit according to one or more embodiments of the present disclosure.

FIG. 7 is a diagram illustrating a structural feature for ensuring uniform luminance in a curved light emitting display device according to one or more embodiments of the present disclosure.

FIG. 8 is a diagram illustrating a structural feature for making a luminance of each area of a curved light emitting display device uniform and a reflection luminance reflected on the windshield uniform in the cockpit according one or more embodiments of the present disclosure.

FIG. 9 is a cross-sectional view illustrating a structure for reinforcing the viewing angle luminance in a curved light emitting display device according to a first embodiment of the present disclosure.

FIG. 10 is a diagram illustrating a configuration of a curved light emitting display device according to the first embodiment of the present disclosure.

FIG. 11 is a diagram illustrating a structure for controlling a front luminance and a viewing angle luminance in a curved light emitting display device according to a second embodiment of the present disclosure.

FIG. 12 is a diagram illustrating a configuration of a curved light emitting display device according to the second embodiment of the present disclosure.

FIG. 13 is a diagram illustrating a configuration of a curved light emitting display device according to a third embodiment of the present disclosure.

FIG. 14 is a diagram illustrating a configuration of a curved light emitting display device according to a fourth embodiment of the present disclosure.

FIG. 15 is a diagram illustrating a configuration of a curved light emitting display device according to a fifth embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example embodiments of the present disclosure, are merely given by way of example. Therefore, the present disclosure is not limited to the illustrated details. Like reference numerals refer to like elements throughout this disclosure unless otherwise specified. In the following description, where the detailed description of the relevant known function or configuration may unnecessarily obscure an important point of the present disclosure, a detailed description of such known function or configuration may be omitted.

Reference will now be made in detail to the example embodiments of the present disclosure, examples of which are illustrated in the accompanying drawings. Wherever possible, the same reference numbers will be used throughout the drawings to refer to the same or like parts. In this disclosure, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in this disclosure should be understood as follows.

In the present disclosure, where the terms “comprise,” “have,” “include,” and the like are used, one or more other elements may be added unless the term, such as “only,” is used. A element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Further, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked”, “coupled,” or “connected” to another element, that the element may be directly or indirectly “linked”, “coupled,” or “connected” to the another element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, a display apparatus according to various embodiments of the present disclosure will be described in detail with reference to the attached drawings. All the components of each display apparatus according all embodiments of the present disclosure are operatively coupled and configured.

Hereinafter, referring to the attached figures, the present disclosure will be explained. Since a scale of each of elements shown in the accompanying drawings may be different from an actual scale for convenience of description, the present disclosure is not limited to the scale shown in the drawings.

FIG. 1 is a plan view illustrating a schematic structure of a light emitting display device (e.g., electroluminescence display) according to one or more embodiments of the present disclosure. In FIG. 1, X-axis refers to the direction parallel to the scan line, Y-axis refers to the direction parallel to the data line, and Z-axis refers to the height direction of the display device.

Referring to FIG. 1, the light emitting display device comprises a substrate 110, a gate (or scan) driver 200, a pad portion 300, a source driving IC (Integrated Circuit) 410, a flexible circuit film 430, a circuit board 450, and a timing controller 500.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the image information or the video images, may be defined as the most regions of the substrate 110 including central portion, but it is not limited thereto. In the display area AA, a plurality of pixels P are arrayed in a matrix manner. Further, a plurality of scan lines (or gate lines), a plurality of data lines may be disposed as crossing each other. Each of pixels P may be disposed at the crossing area of the scan line in X-axis and the data linein Y-axis.

Here, the pixel P may represent any one of color among red, green and blue or red, green, blue and white. A red pixel, a green pixel and a blue pixel may be gathered or a red pixel, a green pixel, a blue pixel and a white pixel may be gathered to form one unit pixel. For example, each of the pixels representing each color may be called as a ‘sub-pixel’, and it may be explained that these ‘sub-pixels’ form one ‘pixel’. As another example, it may be explained that pixels representing each color are called as ‘pixels BP, RP and GP’, and three or four of these ‘pixels’ are gathered to form one ‘unit pixel UP’. Hereinafter, the latter case will be described.

The non-display area NDA, which is an area not representing the video images, may be defined at the circumference areas of the substrate 110 surrounding all or some of the display area AA. In the non-display area NDA, the gate driver 200 and the pad portion 300 may be formed or disposed.

The gate driver 200 may supply the scan (or gate) signals to the scan lines SL according to the gate control signal received from the timing controller 500 through the pad portion 300. The gate driver 200 may be formed at the non-display area NDA at any one outside of the display area AA on the substrate 110, as a GIP (Gate driver In Panel) type. GIP type means that the gate driver 200 is directly formed on the substrate 110. For example, the gate driver 200 may be configured with shift registers. In the GIP type, the transistors for shift registers of the gate driver 200 are directly formed on the upper surface of the substrate 110.

The pad portion 300 may be disposed in the non-display area NDA at one side edge of the display area AA of the substrate 110. The pad portion 300 may include data pads connected to each of the data lines DL, driving current pads connected to the driving current lines, a high-potential pad receiving a high potential voltage, and a low-potential pad receiving a low potential voltage.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (Chip On Film) or COP (Chip On Plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 may include a timing controller 500. The circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be integrated with the source driving IC 410 into one driving chip and may be mounted on the substrate 110 to be connected to the pad portion 300.

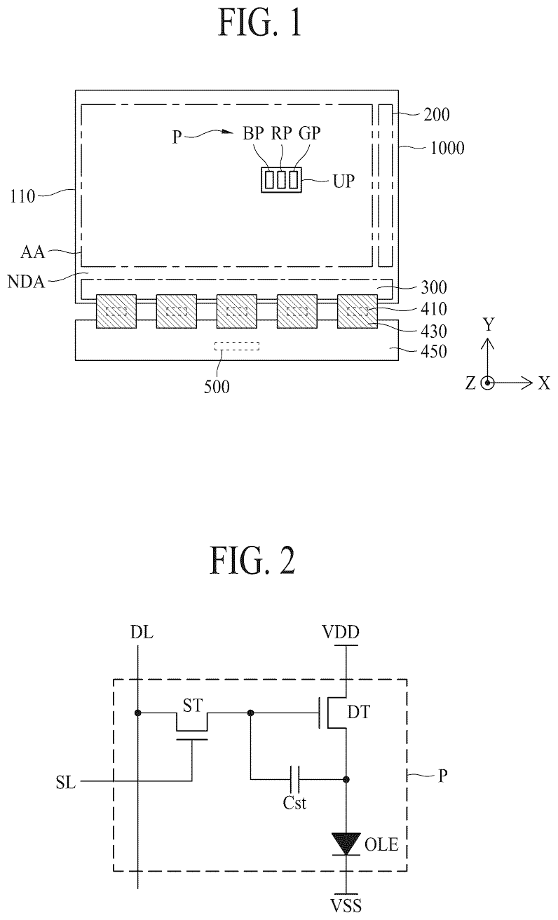

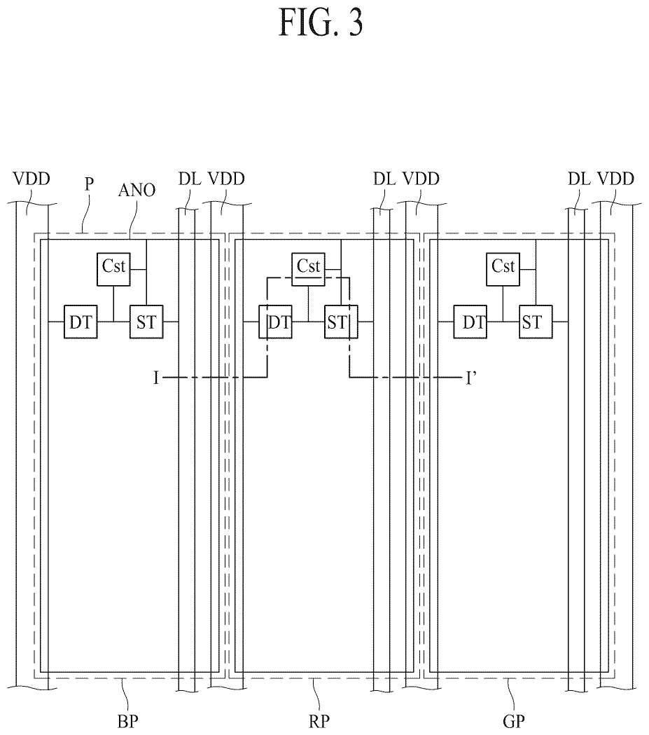

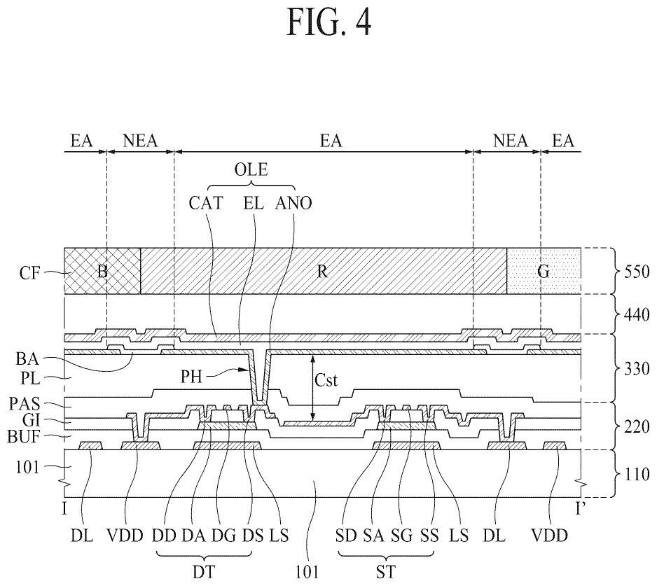

Hereinafter, referring to FIGS. 2 to 4, a detailed structure of a light emitting display device according to one or more embodiments of the present disclosure will be explained. FIG. 2 is a circuit diagram illustrating a structure of one pixel disposed in a light emitting display device according to one or more embodiments of the present disclosure. FIG. 3 is an enlarged plan view illustrating a structure of three pixels sequentially disposed in the light emitting display device according to one or more embodiments of the present disclosure. FIG. 4 is a cross-sectional view, cutting along line I-I′ in FIG. 3, for illustrating a structure of one pixel in a light emitting display device according to one or more embodiments of the present disclosure.

Referring to FIGS. 2 to 4 at first, each pixel P of the light emitting display device according to the present disclosure may be defined by a scan line SL, a data line DL and a driving current line VDD. Each pixel P of the light emitting display device may include a switching thin film transistor ST, a driving thin film transistor DT, a light emitting diode OLE and a storage capacitance (or capacitor) Cst. The driving current line VDD may be supplied with a high-level voltage for driving the light emitting diode OLE.

A switching thin film transistor ST and a driving thin film transistor DT may be formed on a substrate 110. For example, the switching thin film transistor ST may be configured to be connected to the scan line SL and the data line DL crossing with the scan line SL. The switching thin film transistor ST may include a gate electrode SG, a semiconductor layer SA, a source electrode SS and a drain electrode SD. The gate electrode SG of the switching thin film transistor ST may be a portion of the scan line SL. The semiconductor layer SA may be disposed to overlap with the gate electrode SG. The overlapped portion of the semiconductor layer SA with the gate electrode SG may be defined as the channel area. The source electrode SS may be branched from or connected to the data line DL, and the drain electrode SD may be connected to the driving thin film transistor DT. The source electrode SS may be connected to one side of the semiconductor layer SA with respect to the channel area, and the drain electrode SD may be connected to the other side of the semiconductor layer SA with respect to the channel area. By supplying the data signal to the driving thin film transistor DT, the switching thin film transistor ST may play a role of selecting a pixel P which would be driven.

The driving thin film transistor DT may play a role of driving the light emitting diode OLE of the selected pixel P by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be extended from the drain electrode SD of the switching thin film transistor ST. In the driving thin film transistor DT, the drain electrode DD may be branched from or connected to the driving current line VDD, further, the source electrode DS may be connected to the anode electrode (or pixel electrode) ANO of the light emitting diode (or light emitting element) OLE. The semiconductor layer DA may be disposed to overlap with the gate electrode DG. In the semiconductor layer DA, the overlapped portion with the gate electrode DG may be defined as a channel area. The source electrode DS may be connected to one side of the semiconductor layer DA with respect to the channel area, and the drain electrode DD may be connected to the other side of the semiconductor layer DA with respect to the channel area. A storage capacitance (or, capacitor) Cst may be disposed between the gate electrode DG of the driving thin film transistor DT and the anode electrode ANO of the light emitting diode OLE.

The light emitting diode OLE may generate light according to the current controlled by the driving thin film transistor DT. The driving thin film transistor DT may control the amount of current flowing from the driving current line VDD to the light emitting diode OLE according to the voltage difference between the gate electrode DG and the source electrode DS.

The light emitting diode OLE may include an anode electrode ANO, an emission layer EL, and a cathode electrode CAT. The light emitting diode OLE may emit lights according to the current controlled by the driving thin film transistor DT. In other words, the light emitting diode OLE may provide an image by emitting light according to the current controlled by the driving thin film transistor DT. The anode electrode ANO of the light emitting diode OLE may be connected to the source electrode DS of the driving thin film transistor DT. The cathode electrode (or, common electrode) may be connected to a low power line VSS supplied with the low-potential voltage. Therefore, the light emitting diode OLE may be driven by the electric current flown from the driving current line VDD to the low power line VSS controlled by the driving thin film transistor DT.

A plurality of pixels P may be arrayed on the substrate 110. For example, along the horizontal direction, a red pixel RP, a green pixel GP and a blue pixel BP may be sequentially arrayed and disposed. The combination of the red pixel RP, the green pixel GP and the blue pixel BP may configure one unit pixel UP. In another case, the red pixel, the green pixel, the white pixel and the blue pixel may be sequentially arrayed along the horizontal direction. The red pixel, the green pixel, the white pixel and the blue pixel may form a unit pixel. FIG. 3 shows that three pixels, including a red pixel RP, a green pixel GP and a blue pixel BP are sequentially arrayed along the horizontal direction.

Referring to FIG. 4, a cross-sectional structure of the light emitting display device according to one or more embodiments of the present disclosure will be explained. FIG. 4 is a cross-sectional view along to cutting line I-I′ in FIG. 3, for illustrating a structure of one pixel in a light emitting display device according to one or more embodiments of the present disclosure. A light emitting display device may include a substrate 110, a driving element layer 220, a light emitting element layer 330, an encapsulation layer 440 and a color filter layer CF. The driving element layer 220 may include a plurality of thin layers formed on the substrate 110. The driving element layer 220 may include a switching thin film transistor ST and a driving thin film transistor DT.

On the substrate 110, a data line DL, a driving current line VDD and a light shielding layer LS may be formed. The light shielding layer LS may be disposed in an island shape spaced apart from the data line DL and the driving current line VDD by a predetermined distance and overlapping the semiconductor layers SA and DA. In some cases, the light shielding layer LS may be omitted.

A buffer layer BUF is deposited on entire surface of the substrate 110 as covering the driving current line VDD, the data line DL and the light shielding layer LS. On the buffer layer BUF, the semiconductor layer SA of the switching thin film transistor ST and the semiconductor layer DA of the driving thin film transistor DT are formed. The switching thin film transistor ST and the driving thin film transistor DT are formed on the buffer layer BUF. It is preferable that the channel areas in the semiconductor layers SA and DA overlap with the light shielding layer LS.

A gate insulating layer GI is deposited on the substrate 110 as covering the semiconductor layers SA and DA. A gate electrode SG overlapping with the semiconductor layer SA of the switching thin film transistor ST and the gate electrode DG overlapping with the semiconductor layer DA of the driving thin film transistor DT are formed on the gate insulating layer GI. In addition, at both sides of the gate electrode SG of the switching thin film transistor ST, a source electrode SS contacting one side of the semiconductor layer SA while being spaced apart from the gate electrode SG, and a drain electrode SD contacting the other side of the semiconductor layer SA are formed. Further, at both sides of the gate electrode DG of the driving thin film transistor DT, a source electrode DS contacting one side of the semiconductor layer DA while being spaced apart from the gate electrode DG, and a drain electrode DD contacting the other side of the semiconductor layer DA are formed.

The gate electrodes SG and DG, the source electrodes SS and DS, and the drain electrodes SD and DD are formed on the same layer, but are spatially and electrically separated from each other. The source electrode SS of the switching thin film transistor ST may be connected to the data line DL via a contact hole penetrating the gate insulating layer GI. Further, the drain electrode DD of the driving thin film transistor DT may be connected to the driving current line VDD via another contact hole penetrating the gate insulating layer GI.

A passivation layer PAS is deposited on the substrate 110 as covering the thin film transistors ST and DT. The passivation layer PAS may be made of an inorganic material such as silicon oxide (SiOx) or silicon nitride (SiNx).

The light emitting element layer 330 is formed on the driving element layer 220. The light emitting element layer 330 may include a planarization layer PL and a light emitting diode OLE. The planarization layer PL may be a layer used to flatten the uneven surface of the substrate 110 on which the thin film transistors ST and DT are formed. In order to equalize or compensate the height difference due to the uneven surface condition, the planarization layer PL may be formed of an organic material. A pixel contact hole PH may be formed at the passivation layer PAS and the planarization layer PL to expose a portion of the source electrode DS of the driving thin film transistor DT.

An anode electrode (or, pixel electrode) ANO may be formed on the top surface of the planarization layer PL. The anode electrode ANO may be connected to the source electrode DS of the driving thin film transistor DT via a pixel contact hole PH. The anode electrode ANO may have different structure and configuring elements according to the emission type of the light emitting diode OLE. For example, in the case of a bottom emission type that provides lights in the direction of the substrate 110, it may be formed of a transparent conductive material. For another example, in the case of a top emission type that provides lights in the upward direction facing the substrate 110, it may be formed of a metal material having excellent light reflectance. Otherwise, for the case of top emission type emitting light to the upper direction opposite the substrate 110, a reflective layer formed of a metal material with excellent light reflectance may be further included below or above the transparent layer formed of a transparent conductive material. For example, the anode electrode ANO may include any one metal material such as silver(Ag), aluminum (Al), magnesium (Mg), calcium (Ca), gold (Au), copper (Cu), molybdenum (Mo) and titanium (Ti) or alloy metal material thereof.

A bank BA is formed on the top surface of the substrate 110 having the anode electrode ANO. The bank BA is preferably an insulating layer made of an inorganic material or an organic material. Hereinafter, the bank BA made of an inorganic material will be described. The bank BA covers the circumferential areas of the anode electrode ANO, and exposes most of the middle area. The middle area exposed from the bank BA is defined as an emission area EA, and the area covered by bank BA is defined as a non-emission area NEA.

An emission layer EL is disposed on the anode electrode ANO and bank BA. The emission layer EL may be deposited on an entire of the display area AA of the substrate 110 as covering the anode electrode ANO and the bank BA. For example, the emission layer EL may include at least two emission parts for generating white light. In detail, the emission layer EL may include a first emission part and a second emission part vertically stacked for generating white light by mixing the first light from the first emission part and the second light from the second emission part.

For another example, the emission layer EL may include any one of a blue emission part, a green emission part, and a red emission part for generating light corresponding to a color set in each pixel. Further, the light emitting diode OLE may include a functional layer for improving light emitting efficiency and/or lifetime of the emission layer EL.

A cathode electrode (or common electrode) CAT is deposited on the entire surface of the substrate 110 on which the emission layer is formed. The cathode electrode CAT is deposited to make surface contact with the emission layer EL. The cathode electrode CAT is formed over the entire substrate 110 to be commonly connected to the emission layer EL deposited in all pixels. In the case of the bottom emission type, the cathode electrode CAT may include a metal material having excellent light reflectivity with a thickness of 2,000 ∪ or more.

For the top emission type, the cathode electrode CAT may include transparent conductive material. For example, the cathode electrode CAT may be made of a transparent conductive material such as indium-tin-oxide (ITO) or indium-zinc-oxide (IZO). Alternatively, the cathode electrode CAT may include a thin metal such as aluminum (Al), magnesium (Mg), calcium (Ca), silver (Ag) or an alloy or combination thereof (e.g., aluminum-magnesium alloy (AlMg)). It may be formed to have light-transmitting characteristics by forming it with a thin thickness in a range of 20 ∪ to 300 ∪. The present disclosure may be related to the top emission type light emitting display device.

An encapsulation layer 440 is stacked on the light emitting element layer 330. The encapsulation layer 440 may have a single-layer structure made of an inorganic material, or a multi-layer structure in which several inorganic layers are sequentially stacked. As another example, the encapsulation layer 440 may have a structure in which an inorganic layer, an organic layer and an inorganic layer are continuously stacked. Here, for convenience of description, the encapsulation layer 440 made of a single inorganic layer will be used for explanation. The encapsulation layer 440 may be called a capping layer. In some cases, the encapsulation layer 440 may have a structure in which a capping layer and an organic encapsulation layer may be stacked.

A color filter layer 550 is stacked on the encapsulation layer 440. In the color filter layer 550, a plurality of color filters CF may be arranged in a matrix manner to correspond to the arrangement of the pixels P. For example, the color filter CF may be disposed with a structure in which one of a red color filter, a green color filter and a blue color filter is assigned to each pixel P. As another example, the color filter CF may be disposed with a structure in which one of a red color filter, a white color filter, a green color filter and a blue color filter is allocated to each pixel P. Hereinafter, for convenience of description, a case, in which the color filter CF includes a red color filter R, a green color filter G and a blue color filter B, representing the triple primary color light, is used for explanation.

For the case of the top emission type, lights emitted from the emission layer EL of the light emitting diode OLE including the anode electrode ANO, the emission layer EL and the cathode electrode CAT sequentially stacked, may be provided to the outside of the display device through the cathode electrode CAT. In this case, it is required to form the anode electrode ANO with a thickness of 2,000 ∪ to 3,000 ∪ using a metal material with excellent light reflectance. Further, the cathode electrode CAT may preferably be made of a transparent conductive material or, a semi-transparent conductive material.

A light emitting display device having above-mentioned structure may be applied to various fields. In particular, the features of the present disclosure may be applied to a display device for providing information to a driver seat or cockpit of a land transportion, maritime transportation and aero transportation. For example, in the case of automobiles, a single light emitting display device may be placed across the entire dashboard to display various information necessary for driving, operatate various functions, and display various visual information.

### First Embodiment

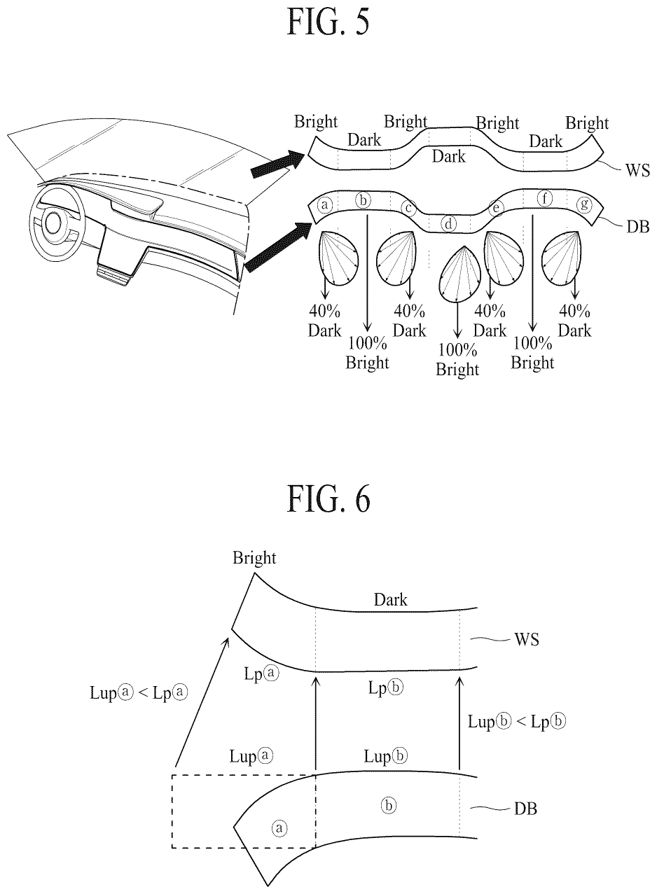

Referring to FIG. 5, the first embodiment of the present disclosure will be explained. The first embodiment describes a case in which a single curved light emitting display device is applied across the entire dashboard of an automobile. FIG. 5 is a diagram illustrating the luminance deviation of each zone of a curved light emitting display device and the reflection luminance deviation reflected on windshield placed above in a cockpit according to one or more embodiments of the present disclosure.

A single curved light emitting display device DB may be placed across the dashboard from the driver seat to the passenger seat of the vehicle. A curved light emitting display device DB may be very long in the lateral (or horizontal) direction and may have a structure in which inflection sections and flat sections are repeatedly and/or alternately arrayed. For example, as shown in FIG. 5, a curved light emitting display device DB may be divided into seven zones. In detail, the curved light emitting display device DB may include seven zones including a zone (a), a zone (b), a zone (c), a zone (d), a zone (e), a zone (f) and a zone (g). These seven zones may be divided into three sections depending on the zone's inflection state. The zone (a) and the zone (e) may be defined as rightward curved sections. The zone (b), the zone (d) and the zone (f) may be defined as flat sections. In addition, the zone (c) and zone (g) may be defined as leftward curved sections.

A curved light emitting display device DB may have high luminance in the front direction, but the luminance may be lowered in the viewing angle directions which may be tilted to the leftward, rightward, upward and downward from the front direction. For example, when the luminance in the front direction may be set to 100%, the luminance in the viewing angle direction may be 40%. Therefore, the luminance of the image information provided to the driver and/or passenger positioned in front of the curved light emitting display device DB may be irregular. For example, the image information provided to the driver from the flat sections may be 100% because it may be provided with the frontal luminance. However, the image information provided to the driver from the curved sections may be 40% of the frontal luminance, because it may be provided with the viewing angle luminance. In FIGS. 5, 100% luminance is referred to ‘Bright’, and 40% luminance is referred to ‘Dark’. It is expressed as relative brightness and darkness.

Since the luminance perceived from the front direction of the curved light emitting display device DB may be irregular or uneven, the driver and/or passengers may not be able to perceive the image information correctly. To prevent this problem, it is necessary to secure uniform or regular luminance in the front direction of the curved light emitting display device DB.

Further, referring to FIG. 6, the luminance (or brightness) distribution of a reflected image WS projected onto a windshield positioned at the upper front of a curved light emitting display device DB. FIG. 6 is schematic diagram explaining the relationship between the luminance of an image provided by a curved light emitting display device mounted on a dashboard and the reflection luminance of an image reflected on a windshield in a cockpit according to the first embodiment. For convenience of explanation, the description will focus on aree (a) and area (b), which are representative areas of the curved section and the flat section of the dashboard.

‘Luminance (or brightness)’ may refer to the brightness of light per unit area (or luminous intensity). The direction tilted to the left relative to the vertical direction on the surface of the curved light emitting display device DB may be defined as the left viewing angle direction. The direction tilted to the right may be defined as the right viewing angle direction. The direction tilted upward may be defined as the upper viewing angle direction. The direction tilted downward may be defined as the lower viewing angle direction. The luminance (or brightness) emitted from the curved light emitting display device DB may have a frontal luminance of 100% measured in the frontal direction and a viewing angle luminance of 40% to 60% measured in each of the upward, downward, leftward and rightward viewing angle directions.

Since the windshield is positioned toward the upper side of the dashboard DB, the viewing angle luminance emitted in the upper viewing angle direction, that is the ‘upward viewing angle luminance’, may be reflected on the windshield. The luminance (or brightness) provided to the windshield may be defined as ‘projected luminance (projected brightness)’. Further, the luminance (or brightness) reflected from the windshield may be defined as ‘reflected luminance (reflected brightness)’. Here, upward viewing angle luminance refers to the luminance emitted from the curved light emitting display device DB to the driver. The projected luminance refers to the luminance provided to the windshield from the curved display device DB. The reflected luminance refers to the luminance reflected from the windshield to the driver.

The upward viewing angle luminance emitted from zone (a) may be identical to the upward viewing angle luminance Lup(a) provided by the shape in which the curved section is unfolded as indicated by the dotted line in FIG. 6. The appearance of zone (a) which is the curved section, reflected on the windshield may be the curved shape reflected on the windshield. Therefore, the unfolded area may be projected onto the windshield as a narrow area in a curved shape. That is, when the upward viewing angle luminance Lup(a) emitted from zone (a) which is the curved section is projected onto the windshield, the area may become narrower and the luminace per unit area may be increased. As a result, the projection luminance Lp(a) may be higher than the upward viewing angle luminance Lup(a).

On the other hand, the appearance of zone (b) which is the flat section, reflected on the windshield may be reflected on the windshield, as it is. Therefore, when the upward viewing angle luminance Lup(b) emitted from zone (b) which is the flat section, may be projected onto the windshield, no overlapping portion may occur. As a result, the projection luminance Lp(b) of zone (b) which is the flat section, projected onto the windshield may be equal to the upward viewing angle luminance Lup(a).

The reflected luminance of the reflected image WS on the windshield may be proportional to the projected luminance. Therefore, as shown in FIG. 5, the reflected luminance resulted in projected from the curved section and reflected by the windshield may be perceived as relatively bright state. On the contrary, the reflected luminance resulted in projected from the flat section and reflected by the windshield may be perceived as relatively dark state. As a result, the reflected luminance of the reflected image WS projected on the windshield may have a luminance distribution opposite to the frontal luminance distribution of the curved light emitting display device DB.

For example, the reflected luminance corresponding to zone (a) having dark frontal luminance may be bright, and the reflected luminance corresponding to zone (b) having bright frontal luminance may be dark. Also, the reflected luminance corresponding to zone (c) having dark frontal luminance may be bright, and the reflected luminance corresponding to zone (d) having bright frontal luminance may be dark. Further, the reflected luminance corresponding to zone (e) having dark frontal luminance may be bright, and the reflected luminance corresponding to zone (f) having bright frontal luminance may be dark. The reflected luminance corresponding to zone (g) having dark frontal luminance may be bright.

The cockpit system including curved light emitting display device according to the present disclosure may have a structure in which the luminance of the curved light emitting display device provided to the driver and/or passenger may be evenly distributed. In addition, the first embodiment may present the structural features for providing uniform reflected luminance of the reflected image projected on the windshield, which is one component of the cockpit system. In the description of the first embodiment, the structural features for providing uniform luminance of a curved light emitting display device will be firstly explained. Next, the structural features for providing uniform reflected luminance of the reflected image projected onto the windshield will be described.

Here, “the luminance is regular or uniform,” “the luminance is same,” “there is no luminance deviation” or equivalent expressions may not simply mean that the luminance is completely identically distributed. These expressions may mean that even though there is a difference in luminance distribution, that is, a deviation in luminance exists, the amount of the deviation may not be perceptible to observer. These may have the same meaning as “luminance devication is out of the perceptual range,” “luminance deviation is within the valid perceptural tolerance range,” “luminance deviation is not perceptible” or an equivalent description.

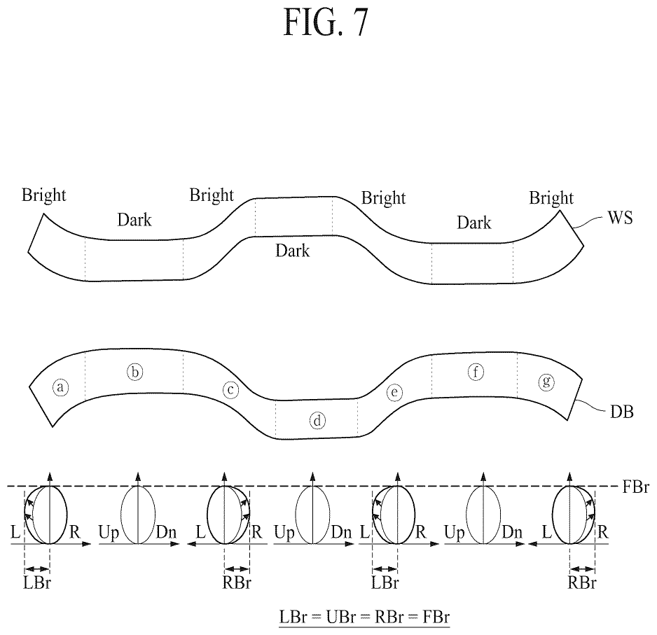

Hereinafter, referring to FIG. 7, structural features for making the luminance uniform in the front direction of a curved light emitting display device DB will be explained. FIG. 7 is a diagram illustrating a structural feature for ensuring uniform luminance in a curved light emitting display device according to the first embodiment of the present disclosure.

FIG. 7 illustrates the luminance distribution of the light provided from seven zones of a curved light emitting display device DB. Further, FIG. 7 illustrates the luminance compensation distribution to make the frontal luminance uniform. For example, the image information provided from the rightward curved section (i.e., zone (a) and zone (e)) may be provided as a luminance of the left viewing angle (i.e., left viewing angle luminance). Therefore, by improving the left viewing angle luminance LBr at the rightward curved section, the image information provided from the rightward curved section may be configured to have the same luminance as the frontal luminance FBr of the flat section. In the interim, the image information provided from the leftward curved section (i.e., zone (c) and zone (g)) may be provided as a luminance of the right viewing angle (i.e., right viewing angle luminance). Therefore, by improving the right viewing angle luminance RBr at the leftward curved section, the image information provided from the leftward curved section may be configured to have the same luminance as the frontal luminance FBr of the flat section.

With the above-mentioned configuration, the image information provided from the curved light emitting display device DB may be observed with uniform luminance when viewed from the front of the display device. By configuring the left viewing angle luminance LBr of the rightward curved section and the right viewing angle luminance RBr of the leftward curved section to be same as or similar to the frontal luminance FBr of the flat section, an image information having uniform luminance distribution may be provided to the driver and/or passenger.

However, when a curved light emitting display device DB is applied to the dashboard of a car, a reflected image WS may appear on the windshield. In such cases, the reflected image WS may have non-uniform luminance distribution. The luminance of a reflected image WS may be mainly affected by the luminance in the upward viewing angle direction of the image provided by the curved light emitting display device DB. Therefore, even though the luminance provided from the curved light emitting display device DB may become uniform, the problem of luminance non-uniformity in the reflected image WS may still exist. That is, as shown in FIG. 7, the reflected image WS may have a luminance with non-uniform state in which ‘Bright’ area and ‘Dark’ area are repeated in the lateral (or horizontal) direction.

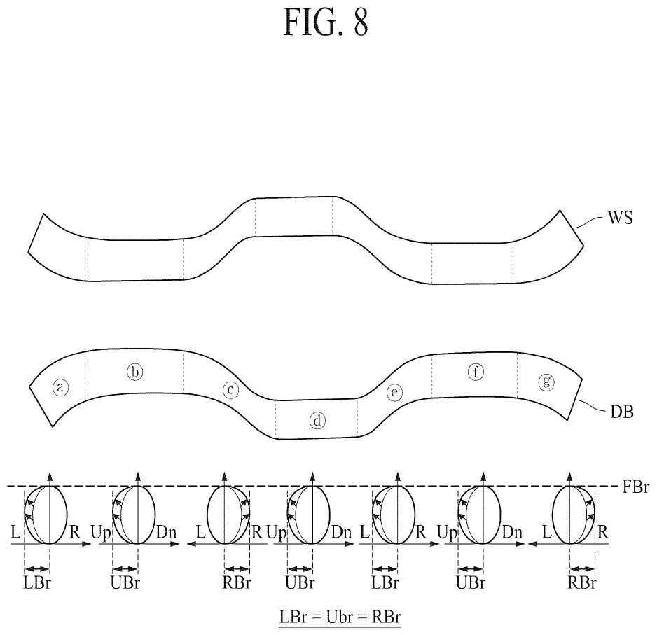

Referring to FIG. 8, structural features for making uniform the front luminance of a curved light emitting display device according to the first embodiment of the present disclosure and the reflection luminance of a reflected image projected onto a windshield may be described. FIG. 8 is a diagram illustrating a structural feature for making a luminance of each area of a curved light emitting display dvice uniform and a reflection luminance reflected on the windshield uniform in the cockpit according to the first embodiment of the present disclosure.

In the luminance of the reflected image WS reflected on the windshield, luminance non-uniformity (unevenness) may occur, as described in FIG. 6. FIG. 8 illustrates a luminance compensation distribution for making both the frontal luminace and the luminance of the reflected image uniform. The image information provided from the rightward curved section (zone (a) and zone (e)) may be presented with a luminance of the left viewing angle direction. Therefore, by improving the left viewing angle luminance LBr of the rightward curved section, the image information provided from the rightward curved section may be configured to have the same as or similar to the luminance of the frontal luminance FBr of the flat section. In the interim, the image information provided from the leftward curved section (zone (c) and zone (g)) may be presented with a luminance of the right viewing angle direction. Therefore, by improving the right viewing angle luminance RBr of the leftward curved section, the image information provided from the leftward curved section may be configured to have the same as or similar to the luminance of the frontal luminance FBr of the flat section.

In addition, since upward viewing angle luminance of the flat sections (zone (b), zone (d) and zone(f)) may have the 40% of the frontal luminance, the luminance of the reflected image may be ‘Dark’ state (referring to FIG. 5). Therefore, by improving the upward viewing angle luminance UBr of the flat section, the luminance of the reflected image WS may be uniformly adjusted overall. At this time, it is necessary to maintain the frontal luminance FBr without any change.

For example, as shown in FIG. 8, for the rightward curved section (zone (a) and zone (e)) of the curved light emitting display device DB, the left viewing angle luminance LBr may be improved. The leftward curved section (zone (c) and zone (g)) may be configured to improve the right viewing angle luminance RBr. Further, the flat section (zone (b), zone (d) and zone (f)) may be configured to improve the upward viewing angle luminance UBr. Here, it is preferable to set the left viewing angle luminance LBr of the rightward curved section, the right viewing angle luminance RBr of the leftward curved section, and the upper viewing angle luminance UBr of the flat section to have substantially the same luminance as the frontal luminance FBr of the flat section. As a result, the image information provided from the curved light emitting display device DB mounted on the dashboard of the car may have an overall uniform luminance distribution.

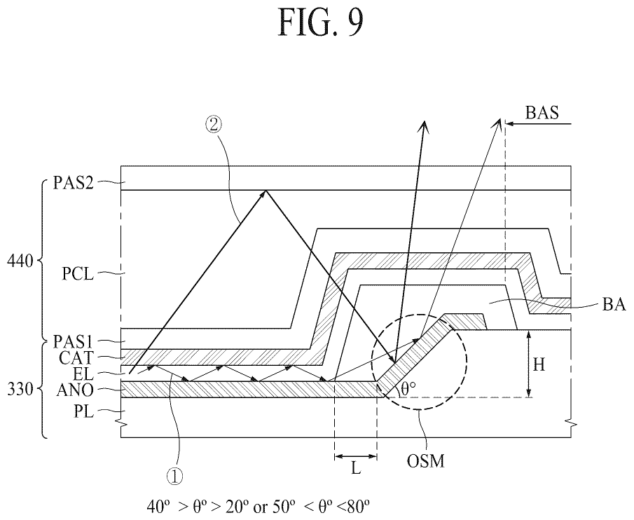

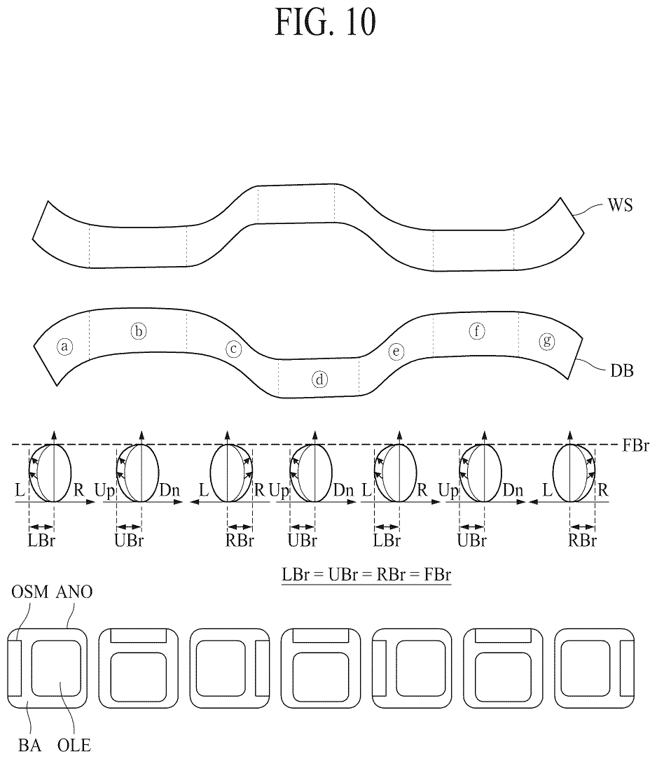

Referring to FIG. 9 and FIG. 10, structural features of a curved light emitting display device for achieving luminance uniformity as shown in FIG. 8 will be explained. FIG. 9 is a cross-sectional view illustrating a structure for reinforcing the viewing angle luminance in a curved light emitting display device according to the first embodiment of the present disclosure. FIG. 10 is a diagram illustrating a configuration of a curved light emitting display device according to the first embodiment of the present disclosure.

Referring to FIG. 9, it is explained about the structural features for improving a viewing angle luminance in a curved light emitting display device according to a first embodiment. Referring to FIG. 9, a curved light emitting display device according to the first embodiment of the present disclosure may have similar structure with the light emitting display device shown in FIG. 4. Difference may be at the structure of the light emitting element layer 330.

For example, the curve light emitting display device according to the first embodiment may have a structure in which a driving element layer 220 may be stacked on a substrate 110 as shown in FIG. 4. Further, a light emitting element layer 330 may be stacked on the driving element layer 220. An encapsulation layer 440 may be stacked on the light emitting element layer 330. Hereinafter, the structure of the light emitting element layer 330 and the encapsulation layer 440 having main features of the first embodiment will be explained.

A light emitting element layer 330 may include a planarization layer PL, an anode electrode ANO, a bank BA, an emission layer EL and a cathode electrode CAT. The planarization layer PL may have a structure in which a middle portion may be recessed, and circumference portion may be protruded with certain height H. From the recessed portion to the protruded portion, the anode electrode ANO may be formed. The anode electrode ANO may have a structure that covers the entire recessed portion (or recession or depression) and extends to a portion of the upper surface of the protruded portion along the slope of the protruded portion. As shown in FIG. 9, for a top emission type display device, the anode electrode ANO may be made of a metal material having excellent light reflectivity. Therefore, the stacked portion along the slope of the planarization layer PL on the anode electrode ANO may be referred to ‘side mirror’ OSM.

On the anode electrode ANO, a bank BA may be formed as covering the protruded portion. The bank BA may be made of a transparent organic material. It is preferable that the bank BA may be formed starting from a position spaced apart from the point where the protruded portionof the planarization layer PL starts to form toward the recessed portion by a certain distance L, and may completely cover the edge of the anode electrode ANO arranged on the upper surface of the protruded portion. Even though the bank BA may completely cover the anode electrode ANO of a pixel, it is preferable that the bank BA does not extend to the anode electrode ANO of neighboring pixels. Therefore, each bank BA between two neighboring pixels may be spaced with certain distance apart from each other. A space between banks BA may be referred to ‘bank slit BAS’. The planarization layer PL may be exposed through the bank slit BAS.

An emission layer EL may be deposited on an upper surface of the anode electrode ANO, the bank BA and the planarization layer PL. A cathode electrode CAT may be deposited on the emission layer EL. An encapsulation layer 440 may be deposited on the cathode electrode CAT. The encapsulation layer 440 may have a structure in which a first inorganic layer PAS1, an organic layer PCL and a second inorganic layer PAS2 sequentially stacked.

With the structure shown in FIG. 9, there may be light traveling in the horizontal direction trapped under total reflection conditions within the emission layer EL. This light may be referred to horizontal (or lateral) propagation light and may be depicted as light path (1). Lights that are totally reflected within the emission layer EL may be lost in the horizontal direction, or dissipated into heat energy within the emission layer EL. However, with a structure such as shown in FIG. 9, these lights may be reflected by the side mirrors and reflected in the direction of the viewing angle. Accordingly, the light emitting display device having the structure shown in FIG. 9 may emit light directly generated from a light emitting diode OLE formed by stacking the anode electrode ANO, the emission layer EL and the cathode electrode CAT, and may additionally emit lights that may be extinguished or lost by the total reflection. As a result, the first embodiment of the present disclosure may present a light emitting display device of which light emitting efficiency is improved and the luminance (or brightness) may be enhanced.

Here, the direction of the reflected light may vary depending on the inclination angle θ of the inclined side of the recessed planarization layer PL. For example, when the inclination angle θ is between 20 degree and 40 degree, the light may be reflected to the right viewing angle direction in FIG. 9. Meanwhile, when the inclination angle θ is between 50 degree and 80 degree, the light may be reflected to the left viewing angle direction in FIG. 9. In other words, when the inclination angle θ is gentle (between 20 degree and 40 degree), the light may be reflected to the viewing angle direction along the inclination side. When the inclination angle θ is steep (between 50 degree and 80 degree), the light may be reflected to the viewing angle direction opposite to the inclination side.

On the contrary, when the inclination angle θ is between 40 degree and 50 degree, the light may be reflected to the frontal direction. In this case, the viewing angle luminance may not increase, but the frontal luminance may increase. Therefore, in order to improve the viewing angle luminance, it is preferable to form the inclined side to have an inclinaction angle between 20 degree and 40 degree, or between 50 degree and 80 degree. When the frontal luminance is to be improved, it is preferable to form the inclined side to have an inclination angle between 40 degree and 50 degree.

For example, when the inclination angle of the side mirror OSM is set to from 20 degree to 40 degree, the light that would otherwise be trapped and extinguished inside the emission layer EL may be further extracted toward the right viewing angle direction. As a result, the right viewing angle luminance may be improved or enhanced.

Further, among the lights generated from the emission layer EL and emitted through the cathode electrode CAT, there may be lights that are totally reflected at the bottom surface of the encapsulation layer 440 and return toward the substrate 110. Some of these lights may be reflected again by the anode electrode ANO or may be propagated toward the substrate 110. The lights reflected from the anode electrode ANO may be emitted through the cathode electrode CAT. However, the lights propagate toward the substrate 110 may be extinguished. The light totally reflected by the encapsulation layer 440 may be referred to the trapped light in the panel and is depicted as light path (2) in FIG. 9.

For example, when there is no side mirror OSM in FIG. 9, the trapped light in the panel may propagate to the substrate 110 through the planarization layer PL. However, with the side mirror as shown in FIG. 9, the trapped light may be reflected by the side mirror OSM and then extracted to the upper side through the cathode electrode CAT. With this case, as described above, according to the inclination angle θ, the light may be extracted to right viewing angle direction or left viewing angle direction. With the structure shown in FIG. 9, the light emitting display device may further extract the lights that may be extinguished without side mirror. Therefore, the light extraction efficiency may be enhanced. Moreover, the viewing angle luminance or frontal luminance may be selectively improved by adjusting the inclination angle of the side mirror OSM.

Hereinafter, referring to FIG. 10, a specific structure of a curved light emitting display device according to the first embodiment of the present disclosure will be explained. FIG. 10 is a diagram illustrating a configuration of a curved light emitting display device according to a first embodiment of the present disclosure. A curved light emitting display device according to FIG. 10 may have a structure in which the side mirror OSM explained in FIG. 9 may be disposed at one side of each pixel. In convenience, the cross-sectional structure of the first embodiment may not be explained because it is the same as shown in FIG. 9. The description for the first embodiment may be focused on the plan view illustrating the position of the side mirror OSM to explain one of the features of the first embodiment.

Referring to FIG. 10, the curved light emitting display device DB may include zone (a), zone (b), zone (c), zone (d), zone (e), zone (f) and zone (g). Pixel disposed in each zone may have an anode electrode ANO. A bank BA may be formed as covering circumference of the anode electrode ANO. A side mirror OSM may be disposed at one side of the pixel. According to the position of the side mirror OSM, a viewing angle may be improved to specific direction.

In the curved light emitting display device shown in FIG. 10, a light emitting diode OLE may be formed at portions of the anode electrode ANO which is not covered by the bank BA. In order to ensure that the pixels arranged in each zone may have the same luminance, it is preferable that the light emitting diodes OLE may be formed to have the same area. Further, it is preferable that the side mirror OSM may be formed with the same size and same inclination angle, and may be placed at the direction of the viewing angle that is to be improved.

For example, in the rightward curved section (zone (a) and zone (e)) of the curved light emitting display device DB, it is preferable to improve the left viewing angle luminance LBr. To do so, a side mirror OSM may be placed on the left side of the anode electrode ANO. Here, by adjusting the inclination angle of the side mirror OSM to between 20 degree and 40 degree, the left viewing angle luminance LBr may be improved.

Further, in the leftward curved section (zone (c) and zone (g)) of the curved light emitting display device DB, it is preferable to improve the right viewing angle luminance RBr. To do so, a side mirror OSM may be placed on the right side of the anode electrode ANO. Here, by adjusting the inclination angle of the side mirror OSM to between 20 degree and 40 degree, the right viewing angle luminance RBr may be improved.

In addition, in the flat section (zone (b), zone (d) and zone (f)) of the curved light emitting display device DB, it is preferable to improve the upward viewing angle luminance UBr. To do so, a side mirror OSM may be placed on the upper side of the anode electrode ANO. Here, by adjusting the inclination angle of the side mirror OSM to between 20 degree and 40 degree, the upward viewing angle luminance UBr may be improved.

As a result, the left viewing angle luminance LBr of the rightward curved section, the right viewing angle luminance RBr of the leftward curved section and the upward viewing angle luminance UBr of the flat section may be adjusted to have substantially the same luminance as the frontal luminance FBr of the flat section. Therefore, the image information provided from the curved light emitting display device DB mounted on the dashboard of a car may have uniform luminance overall. Moreover, the reflection image WS reflected by the windshield of the car may also have uniform luminance overall.

According to the first embodiment, the curved light emitting display device DB may provide with an image having uniform luminance distribution to the observer. At the same time, the reflection image projected onto the windshield may also have uniform luminance distribution. Therefore, while the driver (and/or passenger) may provide with excellent video image, the driver's view may not be disturbed by the luminance deviation of the reflected image.

### Second Embodiment

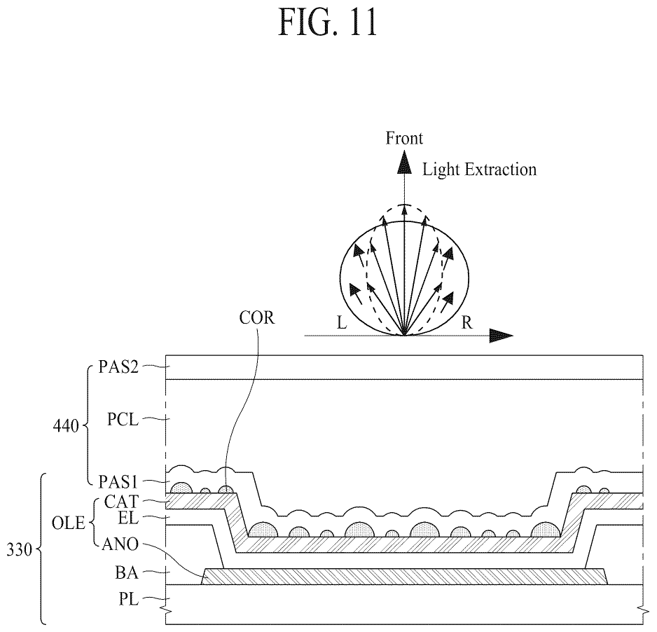

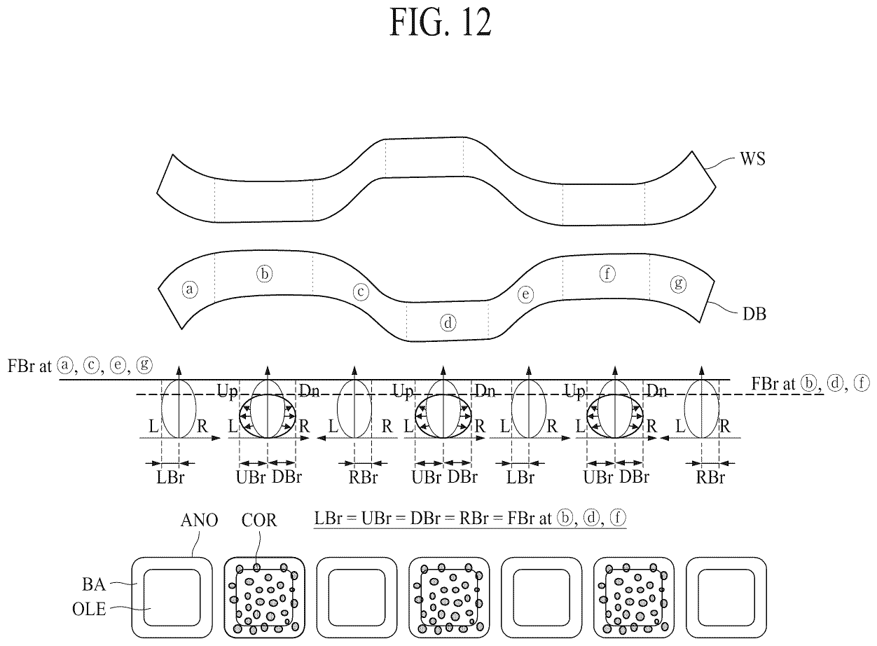

Referring to FIG. 11 and FIG. 12, the second embodiment of the present disclosure will be explained. FIG. 11 is a diagram illustrating a structure for controlling a front luminance and a viewing angle luminance in a curved light emitting display device according to the second embodiment of the present disclosure. FIG. 12 is a diagram illustrating a configuration of a curved light emitting display device according to the second embodiment of the present disclosure.

Referring to FIG. 11, a curved light emitting display device according to the second embodiment may include a light emitting element layer 330 and an encapsulation layer 440 stacked on the light emitting element layer 330. Other elements may have a very similar structure as the curved light emitting display device shown in FIG. 4. The different features of the second embodiment may be that a plurality of protrusions COR may be disposed on the upper surface of the cathode electrode CAT.

A plurality of protrusions COR may be dispersed over a light emitting diode OLE. The plurality of protrusions COR may be formed of a transparent material with sizes ranging from tens to hundreds of nanometers. For example, the cathode electrode CAT may include a transparent conductive material such as indium tin oxide (ITO) or indium zinc oxide (IZO). By precipitating indium to be deposited on the surface of the cathode electrode CAT, nano-sized indium particles may be dispersed to form the protrusions COR. The protrusions COR may have a spherical or hemispherical shape with similar size. However, it is not limited thereto. The protrusions COR may have different size, or may be elliptical sphere or hemi-elliptical spherer shape. The protrusions COR may be irregularly distributed on the cathode electrode CAT. However, it is not limited thereto. The protrusions COR may be distributed in a regular array pattern or manner.

Light emitted from the emission layer EL of the light emitting diode OLE may be scattered and emitted to the outside as it passes through the protrusions COR. Accordingly, it may have a luminance distribution in which the frontal viewing angle luminance may decrease and the viewing angle luminance may increase, compared to when there is no protrusions COR.

Hereinafter, referring to FIG. 12, a structure of the curved light emitting display device according to the second embodiment will be explained. The curved light emitting display device according to the second embodiment may have the features of providing uniform luminance distribution to the observer, while also providing uniform luminance of the reflection image reflected on the windshield to the observer.

Referring to FIG. 12, for an observer positioned in front of the curved light emitting display device DB, the flat section may provide the image with the frontal luminance, the rightward curved section may provide the image with the left-viewing angle luminance, and the leftward curved section may provide the image with the right-viewing angle luminance. For the related general light emitting display device, the viewing angle luminance may be lower than the frontal luminance. For example, the viewing angle luminance may be 40% to 60% of the frontal luminance.

The second embodiment may provide a curved light emitting display device in which the frontal luminance of pixels arranged in flat section (zone (b), zone (d) and zone (f)) is reduced to the level of a viewing angle luminance. To do so, the curved light emitting display device according to the second embodiment may have a feature that the protrusions COR may be disposed at only the pixels arranged in a flat section. On the other hand, protrusions COR may not be disposed in the rightward curved section (zone (a) and zone (e)) and the leftward curved section (zone (c) and zone (g)). As a result, the left viewing angle luminance LBr of the rightward curved section (zone (a) and zone (e)), the frontal luminance FBr of the flat section (zone (b), zone (d) and zone (f)), and the right viewing angle luminance RBr of the leftward curved section (zone (c) and zone (g)) may have substantially the same luminance. Accordingly, the curved light emitting display device according to the second embodiment may provide image information with uniform luminance distribution to the observer.

For the pixels with the protrusions COR, the luminance may increase in all direction viewing angle including the left viewing angle, the right viewing angle, the upward viewing angle and downward viewing angle, but the frontal luminance may decrease. Therefore, the images reflected on the windshield may have a luminance in which the upward viewing angle luminance of the pixel arranged in the flat section may be improved. Therefore, the reflection image WS reflected on the windshield may also have uniform luminance distribution.

According to the second embodiment, the observer seeing the curved light emitting display device DB may provide with a image information having uniform luminance distribution. Moreover, the reflection image on the windshield may have uniform luminance distribution. Therefore, the observer may be provided with excellent image information while not being disturbed by the luminance deviation of the reflection image.

In the first embodiment, by using the side mirror OSM, image information may be provided with uniform luminance to a driver observing a curved light emitting display device which is long in the lateral direction. At the same time, the reflection image reflected on the windshield may also be provided with uniform luminance distribution. Meanwhile, in the second embodiment, reducing the frontal luminance down to a level of the viewing angle luminance by applying the protrusions COR, image information may be provided with uniform luminance to a driver observing a curved light emitting display device which is long in the lateral direction. At the same time, the reflection image reflected on the windshield may also be provided with uniform luminance distribution.

The following explanations may describe various embodiments in which a combination of a side mirror OSM and protrusions COR may be configured to provide image information with uniform luminance distribution to the observer located in front of the curved light emitting display device having long lateral width, while also providing a reflection image on a windshield with uniform luminance distribution.

### Third Embodiment

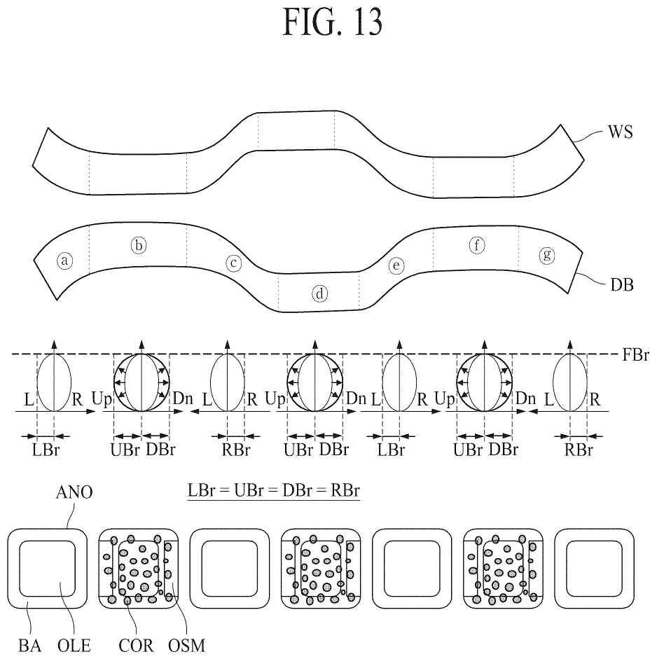

Hereinafter, referring to FIG. 13, the third embodiment of the present disclosure will be explained. FIG. 13 is a diagram illustrating a configuration of a curved light emitting display device according to the third embodiment of the present disclosure.

According to the second embodiment explained with FIG. 12, the curved light emitting display device DB may have a structure in which the frontal luminance may be reduced and the viewing angle luminance may be increased by the protrusions COR. As the viewing angle luminance increases, the luminance of the portion corresponding to the flat section with low luminance among the reflection image WS reflected on the windshield may increase, so that the luminance of the overall reflection image WS may have uniformed distribution.

However, in the curved light emitting display device according to the second embodiment, there may be cases where the frontal luminance of the flat section may become excessively lower than the viewing angle luminance of the curved section due to the protrusions COR. To prevent this problem, there may be a method of placing protrusions COR only on some of the pixels arranged in a flat section. For example, a plurality of protrusions COR may be formed at only 40% to 80% of the pixels among the pixels arranged in a flat section. However, even though this method is used, the frontal luminance of the flat section may become excessively low.

In the third embodiment, a structure is proposed to prevent the problem of excessive reduction in luminance of a flat section in a curved light emitting display device DB that may occur in the structure according to the second embodiment. In detail, a curved light emitting display device DB according to the third embodiment may further include side mirrors OSM in the pixels arranged in the flat section (zone (b), zone (d) and zone (f)) of the structure described in the second embodiment. In this case, it is preferable to configure the side mirror OSM to have a structure to improve the frontal luminance.

For example, the pixels arranged in the flat section (zone (b), zone (d) and zone (f)) may include an anode electrode ANO, a bank BA and a side mirror OSM. The bank BA may cover circumferences of the anode electrode ANO. Side mirrors OSM may be disposed at the left side and the right side of the anode electrode ANO. In particular, it is preferable that the inclination angle θ of the side mirror OSM may be between 40 degree and 50 degree. As a result, the frontal luminance which may be lowered by the protrusions COR may be enhanced by the side mirror OSM.

A curved light emitting display device according to the third embodiment may have a structure for improving frontal luminance that may have been excessively lowered by the protrusions COR in a flat section. Here, rather than maximizing the frontal luminance FBr of the flat section (zone (b), zone (d) and zone (f)), it is preferable to improve the frontal luminance to the same level as the left viewing angle luminance LBr of the rightward curved section (zone (a) and zone (e)) and the right viewing angle luminance RBr of the leftward curved section (zone (c) and zone (g)).

In addition, the curved light emitting display device according to the third embodiment may have a structure in which the upward viewing angle luminance UBr and the downward viewing angle luminance DBr of the flat section (zone (b), zone (d) and zone (f)) may be improved. Therefore, the luminance of the reflection image WS projected onto the windshield corresponding to the flat section may be improved. As a result, the luminance distribution may be maintained uniformly over the entire area of the reflection image WS projected onto the windshield.

The curved light emitting display device DB according to the third embodiment may provide an image information having uniform luminance distribution to the observer. At the same time, the reflection image on the windshield may also have uniform luminance distribution. Accordingly, while being provided with an excellent quality of image information, there is no visual disturbance caused by luminance deviation of the reflection image.

### Fourth Embodiment

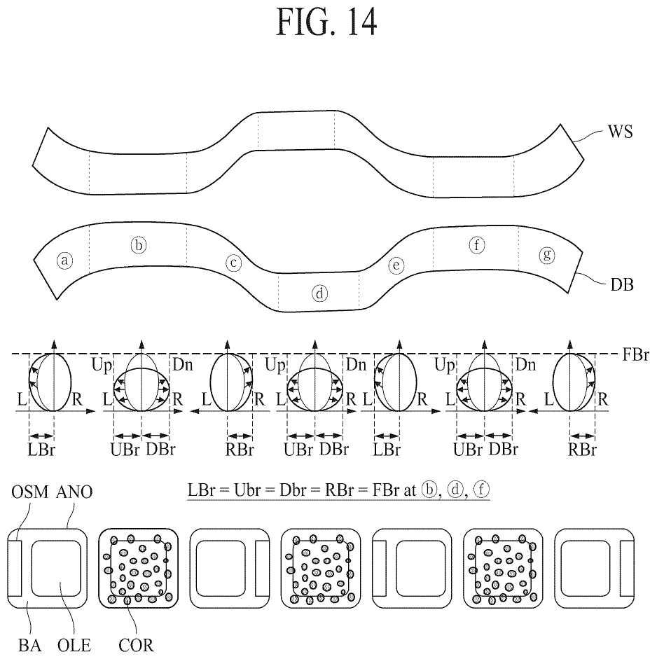

Hereinafter, referring to FIG. 14, the fourth embodiment of the present disclosure will be explained. FIG. 14 is a diagram illustrating a configuration of a curved light emitting display device according to the fourth embodiment of the present disclosure.

The curved light emitting display device according to the third embodiment may have a structure that may solve the problem of the frontal luminance of a flat section being excessively lower than the viewing angle luminance of curved sections due to the protrusions COR in the curved light emitting display device according to the second embodiment. On the contrary, in a curved light emitting display device according to the second embodiment, by applying the protrusions COR in a flat section, even though the frontal luminance is lowered, the frontal luminance may still be higher than the viewing angle luminance of the curved section. The fourth embodiment may propose a curved light emitting display device having a structure for preventing such problem.

A curved light emitting display device according to the fourth embodiment may have a structure in which a plurality of protrusions COR may be placed in the flat section (zone (b), zone (d) and zone (f)) to decrease the frontal luminance and to increase the viewing angle luminance. Further, since there is no protrusions COR in the rightward curved section (zone (a) and zone (e)) and the leftward curved section (zone (c) and zone (g)), the viewing angle luminance may be lower than the frontal luminance.

Under this condition, the frontal luminance of the flat section (zone (b), zone (d) and zone (f)) may be higher than the left viewing angle luminance of the rightward curved section (zone (a) and zone (e)) and the right viewing angle luminance of the leftward curved section (zone (c) and zone (g)). As a result, the image provided from the curved light emitting display device may have unevenly distributed luminance overall of the entire display.

To solve this problem, a curved light emitting display device according to the fourth embodiment may have a structure in which the rightward curved section (zone (a) and zone (e)) may be configured to increase the left viewing angle luminance, and the leftward curved section (zone (c) and zone (g)) may be configured to increase right viewing angle luminance. For example, side mirror OSM may be disposed at the left side of the rightward curved section (zone (a) and zone (e)). Additionally, side mirror OSM may be disposed at the right side of the leftward curved section (zone (c) and zone (g)).

With the above structure, it is preferable to adjust the inclination angle of the side mirror OSM to between 20 degree and 40 degree. As a result, the left viewing luminance LBr of the rightward curved section (zone (a) and zone (e)) and the right viewing angle luminance RBr of the leftward curved section (zone (c) and zone (g)) may be improved to be the same as the frontal luminance of the flat section (zone (b), zone (d) and zone (f)).

The curved light emitting display device DB according to the fourth embodiment may provide an image information having uniform luminance distribution to the observer. At the same time, the reflection image on the windshield may also have uniform luminance distribution. Accordingly, while being provided with an excellent quality of image information, there is no visual disturbance caused by luminance deviation of the reflection image.

### Fifth Embodiment

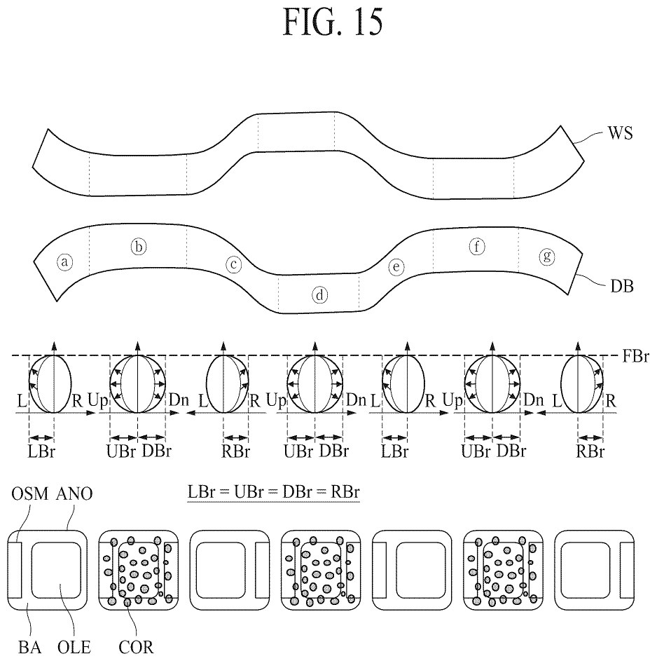

Hereinafter, referring to FIG. 15, the fifth embodiment of the present disclosure will be explained. FIG. 15 is a diagram illustrating a configuration of a curved light emitting display device according to the fifth embodiment of the present disclosure.

In the third embodiment, the structure is described that solves one problem that occurs in the second embodiment, in which the frontal luminance in the flat section is excessively lower than the viewing angle luminance in the curved section. Moreover, in the fourth embodiment, the structure is described that solves another problem that occurs in the second embodiment, in which the frontal luminance in the flat section remains higher than the viewing angle luminance in the curved section. In the fifth embodiment, a structure to most efficiently solve the unevenness problem of luminance distribution that occurs in the second embodiment will be described. The curved light emitting display device according to the fifth embodiment may have a structural feature in which the structure according to the third embodiment may be combined with the structure according to the fourth embodiment.

For example, a curved light emitting display device according to the fifth embodiment may include a curved section and a flat section. The curved section may include a rightward curved section (zone (a) and zone (e)) and a leftward curved section (zone (c) and zone (g)). The flat section (zone (b), zone (d) and zone (f)) may be disposed between tow curved sections.

Each of the pixels arranged in the rightward curved section (zone (a) and zone (e)) and the leftward curved section (zone (c) and zone (g)) may include an anode electrode ANO, a bank BA and a side mirror OSM. The side mirror OSM disposed at the rightward curved section may be placed at the left side of the pixel. Further, the side mirror OSM disposed at the leftward curved section may be placed at the right side of the pixel. Here, it is preferable that the inclination angle may be set between 20 degree and 40 degree. As a result, the pixels disposed at the rightward curved section may have enhanced left viewing angle luminance LBr. Further, the pixels disposed at the leftward curved section may have enhanced right viewing angle luminance RBr.

Each of the pixels disposed at the flat section may include an anode electrode ANO, a bank BA, a side mirror OSM and a plurality of protrusions COR. Due to the protrusions COR disposed at the pixels in the flat section, the pixels in the flat section may have lowered frontal luminance. Therefore, the luminance of the portion corresponding to the flat section in the refletion image WS projected on the windshield may be increased. Accordingly, the reflection image WS may be configured to have uniform luminance distribution.

Further, each of the pixels disposed in the flat section may have side mirrors OSM at the left side and the right side of the pixel. Here, it is preferable that the inclination angle of the side mirror OSM may be between 40 degree and 50 degree. As a result, due to the side mirrors OSM, the frontal luminance of the pixels in the flat section lowered by the protrusions COR may be increased a lot.

The curved light emitting display device according to the fifth embodiment may include various elements for adjusting the viewing angle luminance and the frontal luminance at each of the curved sections and the flat sections. Therefore, by variously applying the structures of the elements for adjusting the frontal luminance and the viewing angle luminance, the frontal luminance and the viewing angle luminance may be optimally adjusted. As a result, the left viewing angle luminance LBr of the rightward curved section (zone (a) and zone (e)), the right viewing angle luminance RBr of the leftward curved section (zone (c) and zone (g)) may be adjusted to have simultaneously same level of the frontal luminance of the flat section (zone (b), zone (d) and zone (f)). Further, the reflection image WS projected onto the windshield may be configured to have uniform luminance distribution.

The curved light emitting display device DB according to the fifth embodiment may provide an image information having uniform luminance distribution to the observer. At the same time, the reflection image on the windshield may also have uniform luminance distribution. Accordingly, while being provided with an excellent quality of image information, there is no visual disturbance caused by luminance deviation of the reflection image.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

What is claimed is:

1. A curved light emitting display device, comprising:
a substrate;
a flat section on the substrate;
a rightward curved section disposed at one side of the flat section on the substrate; and
a leftward curved section disposed at another side of the flat section on the substrate,
wherein a luminance deviation among a left viewing angle luminance of the rightward curved section, a frontal luminance of the flat section and a right viewing angle luminance of the leftward curved section is out of a perceptible range.

2. The curved light emitting display device according to claim 1, wherein a luminance deviation between an upward viewing angle luminance of the flat section and a projected luminance of any one of the rightward curved section and the leftward curved section is out of the perceptible range.

3. The curved light emitting display device according to claim 1, wherein each pixel of a first plurality of pixels in the rightward curved section includes:
a first light emitting diode; and
a first side mirror placed at a left side of the first light emitting diode,
wherein each pixel of a second plurality of pixels in the flat section includes:
a second light emitting diode; and
a second side mirror placed at an upper side of the second light emitting diode, and
wherein each pixel of a third plurality of pixels in the leftward curved section includes:
a third light emitting diode; and
a third side mirror placed at a right side of the third light emitting diode.

4. The curved light emitting display device according to claim 3, each of the first light emitting diode, the second light emitting diode and the third light emitting diode includes:
an anode electrode;
an emission layer on the anode electrode; and
a cathode electrode on the emission layer,
wherein the first side mirror has a first inclined side that corresponds to a left side portion of the anode electrode, the first inclined side extended to a left upward direction,
wherein the second side mirror has a second inclined side that corresponds to an upper side portion of the anode electrode, the second inclined side extended to an upper upward direction, and
wherein the third side mirror has a third inclined side that corresponds to a right side portion of the anode electrode extended to a right upward direction.

5. The curved light emitting display device according to claim 4, wherein the first inclined side, the second inclined side and the third inclined side have an inclination angle between 20 degree and 40 degree or between 50 degree and 80 degree.

6. The curved light emitting display device according to claim 1, further comprising:
a first pixel in the rightward curved section;
a second pixel in the flat section; and
a third pixel in the leftward curved section,
wherein each of the first pixel, the second pixel and the third pixel includes:
an anode electrode;
an emission layer on the anode electrode;
a cathode electrode on the emission layer; and
a passivation layer on the cathode electrode, and
wherein the second pixel further includes protrusions dispersed on the passivation layer.

7. The curved light emitting display device according to claim 6, wherein the second pixel further includes a side mirror having inclined sides that are configured by a left side portion of the anode electrode and a right side portion of the anode electrode being extended to upward directions.

8. The curved light emitting display device according to claim 7, wherein the inclined sides have an inclination angle between 40 degree and 50 degree.

9. The curved light emitting display device according to claim 6, wherein the first pixel includes a first side mirror having a first inclined side that is a left side portion of the anode electrode extended to a left upward direction, and
wherein the third pixel includes a second side mirror having a second inclined side that is a right side portion of the anode electrode extended to a right upward direction.

10. The curved light emitting display device according to claim 9, wherein the first inclined side and the second inclined side have an inclination angle between 20 degree and 40 degree or between 50 degree and 80 degree.

11. The curved light emitting display device according to claim 9, wherein the second pixel further includes a third side mirror having a third inclined side that is a right side portion and a left side portion of the anode electrode extended to an upward direction.

12. The curved light emitting display device according to claim 11, wherein the first inclined side and the second inclined side have an inclination angle between 20 degree and 40 degree or between 50 degree and 80 degree, and
wherein the third inclined side has an inclination angle between 40 degree and 50 degree.

13. A cockpit system comprising:
the curved light emitting display device of claim 1; and
a windshield disposed at a front upper side of the curved light emitting display device of claim 1,
wherein a luminance deviation among the left viewing angle luminance of the rightward curved section, the frontal luminance of the flat section, an upward viewing angle luminance of the flat section and the right viewing angle luminance of the leftward curved section is out of the perceptible range, and
wherein a reflection luminance deviation among a reflection luminance of the rightward curved section, a reflection luminance of the flat section and a reflection luminance of the leftward curved section is out of the perceptible range.

14. A curved light emitting display device, comprising:
a flat section;
a rightward curved section disposed at a first side of the flat section; and
a leftward curved section disposed at a second side of the flat section that is opposite to the first side of the flat section,
wherein a pixel in the leftward curved section includes:
a first anode electrode including a pair of flat portions and a sloped portion between the pair of flat portions, the sloped portion of the first anode electrode extending to a right upward direction,
a first emission layer partially on the first anode electrode, the first emission layer including a pair of flat portions and a sloped portion between the pair of flat portions, and
a first cathode electrode on the first emission layer, the first cathode electrode including a pair of flat portions and a sloped portion between the pair of flat portions, an inclination angle of each of the sloped portion of the first emission layer and the sloped portion of the first cathode electrode being greater than an inclination angle of the sloped portion of the first anode electrode.

15. The curved light emitting display device according to claim 14, wherein a pixel in the rightward curved section includes:
a second anode electrode including a pair of flat portions and a sloped portion between the pair of flat portions, the sloped portion of the second anode electrode extending to a left upward direction;
a second emission layer partially on the second anode electrode, the second emission layer including a pair of flat portions and a sloped portion between the pair of flat portions; and
a second cathode electrode on the second emission layer, the second cathode electrode including a pair of flat portions and a sloped portion between the pair of flat portions, an inclination angle of each of the sloped portion of the second emission layer and the sloped portion of the second cathode electrode being greater than an inclination angle of the sloped portion of the second anode electrode.

16. The curved light emitting display device according to claim 15, wherein the inclination angle of the sloped portion of the first anode electrode is same as the inclination angle of the sloped portion of the second anode electrode.

17. The curved light emitting display device according to claim 14, wherein the pixel in the leftward curved section further includes a first planarization layer having a first recessed portion and a first protruded portion, the first anode electrode covering the first recessed portion and extending to a portion of an upper surface of the first protruded portion along a slope of the first protruded portion.

18. The curved light emitting display device according to claim 17, wherein the sloped portion of the first anode electrode covers an upper surface of the first protruded portion of the first planarization layer along the slope of the first protruded portion of the first planarization layer, a flat portion of the pair of flat portions of the first anode electrode covering the first recessed portion of the first planarization layer, and another flat portion of the pair of flat portions of the first anode electrode is partially disposed on the first protruded portion of the first planarization layer.

19. The curved light emitting display device according to claim 17, wherein the pixel in the leftward curved section further includes a first bank partially disposed on the first protruded portion of the first planarization layer and the first anode electrode.

20. The curved light emitting display device according to claim 15, wherein the pixel in the rightward curved section further includes a second planarization layer having a second recessed portion and a second protruded portion, the second anode electrode covering the second recessed portion and extending to a portion of an upper surface of the second protruded portion along a slope of the second protruded portion.

21. The curved light emitting display device according to claim 20, wherein the sloped portion of the second anode electrode covers an upper surface of the second protruded portion of the second planarization layer along the slope of the second protruded portion of the second planarization layer, a flat portion of the pair of flat portions of the second anode electrode covering the second recessed portion of the second planarization layer, and another flat portion of the pair of flat portions of the second anode electrode is partially disposed on the second protruded portion of the second planarization layer.

22. The curved light emitting display device according to claim 20, wherein the pixel in the rightward curved section further includes a second bank partially disposed on the second protruded portion of the second planarization layer and the second anode electrode.

23. The curved light emitting display device according to claim 14, wherein the pixel in the leftward curved section further includes a first passivation layer on the first cathode electrode, the first passivation layer including a pair of flat portions and a sloped portion between the pair of flat portions, an inclination angle of the sloped portion of the first passivation layer being greater than the inclination angle of the sloped portion of the first anode electrode.

24. The curved light emitting display device according to claim 15, wherein the pixel in the rightward curved section further includes a second passivation layer on the second cathode electrode, the second passivation layer including a pair of flat portions and a sloped portion between the pair of flat portions, an inclination angle of the sloped portion of the second passivation layer being greater than the inclination angle of the sloped portion of the second anode electrode.

25. The curved light emitting display device according to claim 14, wherein the pixel in the leftward curved section further includes a first plurality of protrusions dispersed on the first cathode electrode.

26. The curved light emitting display device according to claim 25, wherein the pixel in the leftward curved section further includes a first passivation layer on the first cathode electrode, and
wherein the pixel in the leftward curved section further includes a second plurality of protrusions dispersed on the first passivation layer.
